(19) United States
(12) Patent Application Publication
(10) Pub. No.: US 2010/0067201 A1
(43) Pub. Date: Mar. 18, 2010

(54) FLIP ELECTRONIC DEVICE

(76) Inventors: Yen-Liang CHEN, Taipei (TW); Ching-Hao YU, Taipei (TW); Meng-Hsuan SHIH, Taipei (TW); Wei-Chun CHIEN, Taipei (TW); Chien-Hsu HOU, Taipei (TW); Martijn BALLER, Taipei (TW); Jia-Rong LIN, Taipei (TW); Yung-Chie HUANG, Taipei (TW); Chi-Chen LIN, Taipei (TW); Chia-Ying LEE, Taipei (TW)

Correspondence Address: Muncy, Geissler, Olds & Lowe, PLLC, P.O. BOX 1364, FAIRFAX, VA, 22038-1364, US

(21) Appl. No.: 12/558,128

(22) Filed: Sep. 11, 2009

(30) Foreign Application Priority Data
Sep. 12, 2008 (TW) 097135142

(51) Int. Cl. H05K 5/00

(52) U.S. Cl. 361/748

(57) ABSTRACT

A flip electronic device includes a cover, a display module, a casing, a circuit board, and an electrical connection element. The casing is pivotally connected with the cover. The cover has a light-transparent portion. The display module is disposed at the cover. The circuit board is disposed in the casing. The electrical connection element is electrically connected with the display module and the circuit board. At least one portion of the electrical connection element is viewable through the light-transparent portion.

### CROSS REFERENCE TO RELATED APPLICATIONS

This Non-provisional application claims priority under 35 U.S.C. §119(a) on Patent Application No(s). 097135142 filed in Taiwan, Republic of China on Sep. 12, 2008, the entire contents of which are hereby incorporated by reference.

### BACKGROUND OF THE INVENTION

1. Field of Invention

The invention relates to a flip electronic device and, more particularly, to a flip electronic device having a light-transparent casing.

2. Related Art

A casing of a general electronic device (such as a display) is often a lightproof frame (such as a metal casing). A display screen is disposed at an opening of the frame. When a user uses the electronic device, he or she often feels that display images are limited by the frame surrounding the display screen. Further, the whole aesthetic is deteriorated.

### SUMMARY OF THE INVENTION

This invention provides an electronic device having a casing with a light-transparent portion. The electronic device provides a display effect of a light-transparent frame to obtain a space feeling with visual extension.

According to one aspect of the invention, the flip electronic device includes a cover, a display module, a casing, a circuit board, and an electrical connection element. The casing is pivotally connected with the cover. The cover has a light-transparent portion. The display module is disposed at the cover. The circuit board is disposed in the casing. The electrical connection element is electrically connected with the display module and the circuit board, and at least one portion of the electrical connection element is viewable through the light-transparent portion.

In one embodiment of the invention, at least one portion of the cover may be made of a light-transparent material. The cover may be formed by combining a half casing made of a light-transparent material and a half casing made of a lightproof material. The light-transparent material may be made of glass or a polymer material. The polymer material may be selected from the group consisting of PC, PS, PVC, ABS, PMMA, MPPO, PSF, PES, PEI, PAI, PU, PET, and a combination thereof. The display module may be exposed via the half casing made of the light-transparent material.

In one embodiment of the invention, the cover may further have an opening, and the display module may be directly exposed to the opening.

In one embodiment of the invention, a pressing assembly or a touching assembly may be disposed at the cover.

In one embodiment of the invention, the electrical connection element may be a wire or a flexible printed circuit.

In one embodiment of the invention, the flip electronic device may be a notebook computer, a tablet computer, a mobile communication device, a personal digital assistant, a global positioning system, or a display.

In one embodiment of the invention, a pressing assembly and/or a touching assembly may be disposed at the casing and be used as an input assembly.

In one embodiment of the invention, the flip electronic device may further include at least one hinge, and the cover may be pivotally connected with the casing via the hinge at one side, two sides, or a plurality of sides. The electrical connection element may pass through the cover and enter into the casing along the hinge, such that the display module may be electrically connected with the circuit board.

To sum up, according to the invention, via the cover disposed as a light-transparent frame, a space feeling with visual extension can be obtained around the display module.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing a flip electronic device according to one preferred embodiment of the invention;

FIG. 2 is a schematic diagram showing a flip electronic device according to another preferred embodiment of the invention; and

FIG. 3 is a side view showing the flip electronic device in FIG. 2.

### DETAILED DESCRIPTION OF THE INVENTION

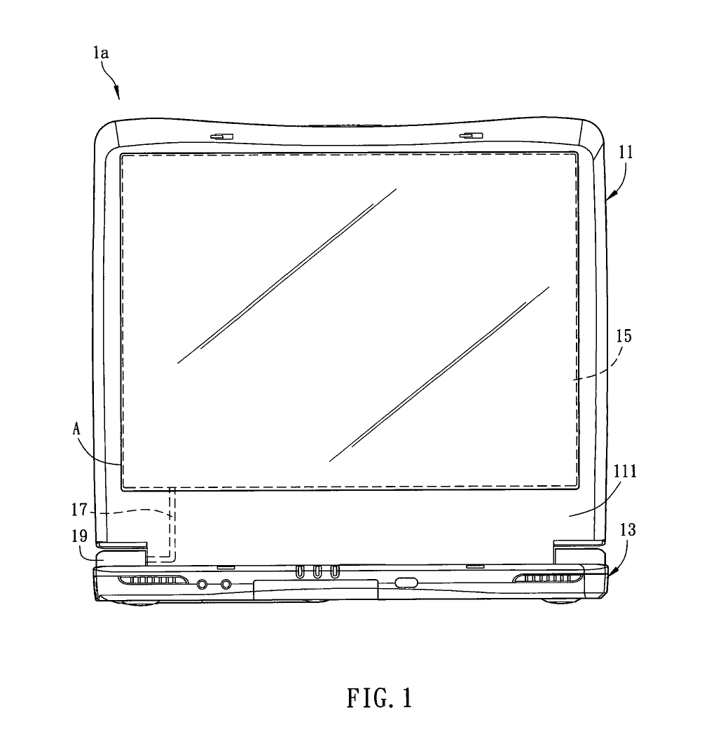

FIG. 1 is a schematic diagram showing a flip electronic device according to one preferred embodiment of the invention. In this embodiment, a notebook computer as a flip electronic device 1a is taken for example. The flip electronic device 1a can also be a tablet computer, a mobile communication device (such as a mobile phone or an intelligent mobile phone), a personal digital assistant (PDA), a global positioning system (GPS), a display, or other portable electronic devices. However, the invention is not limited thereto.

In FIG. 1, the flip electronic device 1a includes a cover 11, a display module 15, a casing 13, a circuit board (not shown), and an electrical connection element 17. The cover 11 has a light-transparent portion 111. The cover 11 around the display module 15 can partly (such as only the bottom) or fully constitute the light-transparent portion 111. The display module 15 is disposed at the cover 11. The display module 15 may be disposed at an opening A of the cover 11, such that the display module 15 is directly exposed to the opening A. However, the invention is not limited thereto.

To make the cover 11 have a light-transparent frame to obtain a space effect with visual extension, at least one portion of the cover 11 can be made of a light-transparent material. In this embodiment, the light-transparent portion 111 is made of PC. However, the invention is not limited thereto. The light-transparent portion 111 may also be made of glass or other polymer materials. The polymer material may be selected from a thermosetting material or a light-setting material such as the group consisting of PC, PS, PVC, ABS, PMMA, MPPO, PSF, PES, PEI, PAI, PU, PET, and a combination thereof. However, the invention is not limited thereto.

The circuit board of the flip electronic device 1a is disposed in the casing 13, and the electrical connection element 17 is electrically connected with the display module 15 and the circuit board. A least one portion of the electrical connection element 17 is viewable through the light-transparent portion 111 of the cover 11. In this embodiment, a wire as the electrical connection element 17 is taken for example. The electrical connection element 17 may also be a flexible printed circuit or other conductive elements.

The light-transparent portion 111 of the cover 11 can be combined with a part of the electrical connection element 17 via in-mold forming (IMF), in-mold decoration (IMD), in-mold roller (IMR), embedded injection molding, insert molding, or co-injection molding and so on. However, the invention is not limited thereto. Two terminals of the part of the electrical connection element 17 exposed to the light-transparent portion 111 are electrically connected with the display module 15 and the circuit board, respectively.

In addition, if the flip electronic device 1a includes a pressing assembly and/or a touching assembly, the pressing assembly and/or the touching assembly are exposed to the casing 13. The pressing assembly and/or the touching assembly may be a standard keyboard, a key, a media key, a function key, or a touchpad. A user can perform an input operation via a physical key and/or a touchpad.

The flip electronic device 1a further includes at least one hinge 19. The cover 11 is pivotally connected with the casing 13 via the hinge 19. In this embodiment, two hinges 19 at two sides are taken for example. However, the cover 11 and the casing 13 of the flip electronic device 1a may also be pivotally connected with each other at one side or a plurality sides. The electrical connection element 17 passes through the light-transparent portion 11 of the cover 11 and enters into the casing 13 along the hinge 19, such that the display module 15 is electrically connected with the circuit board.

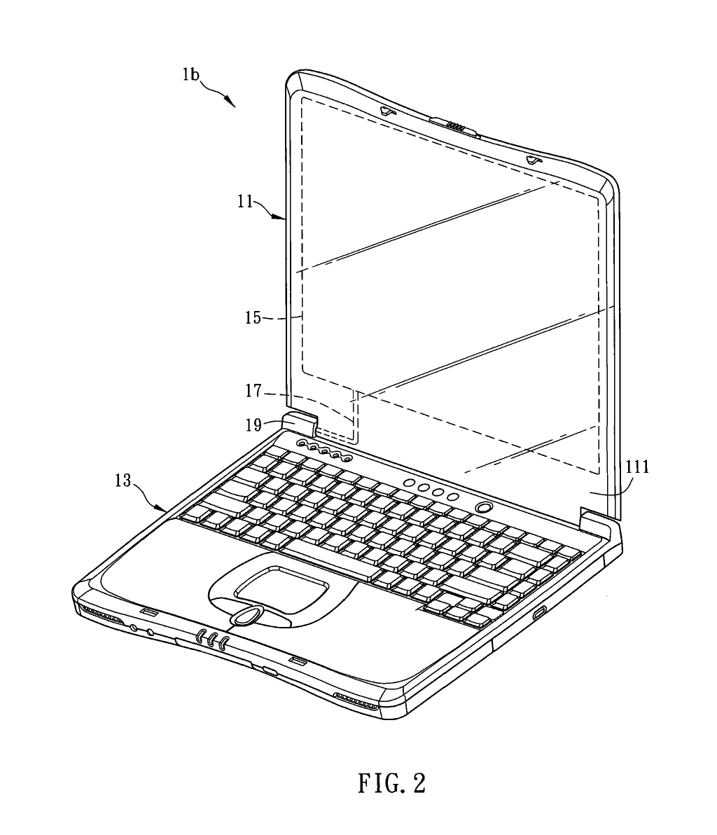

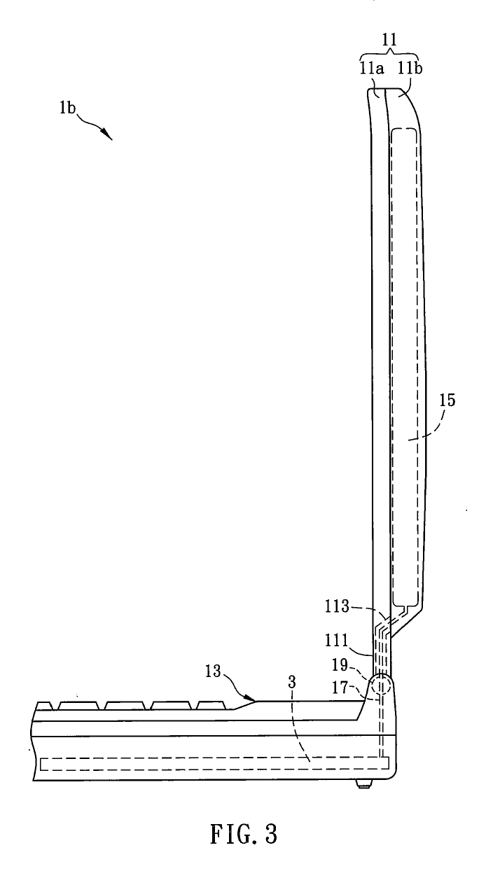

FIG. 2 is schematic diagram showing a flip electronic device according to another preferred embodiment of the invention. FIG. 3 is a side view showing the flip electronic device in FIG. 2. Please refer to FIG. 2 and FIG. 3 together. Different from the flip electronic device 1a in the above embodiment, in the flip electronic device 1b according to this embodiment, the cover 11 is formed by combining a half casing 11a made of a light-transparent material and a half casing 11b made of a lightproof material. In FIG. 3, a display module 15 is disposed in the half casing 11b, such that the display module 15 is exposed indirectly. At that moment, the half casing 11a can be used as a protective element of the display module 15 for preventing the display module 15 from being damaged.

In FIG. 3, an electrical connection element 17 passes through a passage 113 of the light-transparent portion 111 and a hinge 19, and then it enters into a casing 13, such that the display module 15 is electrically connected with a circuit board 3. The passage 113 can be formed in the injection molding process of the light-transparent portion 111. The passage 113 may also be formed in the light-transparent portion 111 via a subsequent process (such as drilling). However, the invention is not limited thereto.

To sum up, according to the invention, via the cover disposed as a light-transparent frame, a space feeling with visual extension can be obtained around the display module.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A flip electronic device comprising:
a cover having a light-transparent portion;
a display module disposed at the cover;
a casing pivotally connected with the cover;
a circuit board disposed in the casing; and
an electrical connection element electrically connected with the display module and the circuit board, at least one portion of the electrical connection element being viewable through the light-transparent portion.

2. The electronic device according to claim 1, wherein at least one portion of the cover is made of a light-transparent material.

3. The electronic device according to claim 2, wherein the light-transparent material is made of glass or a polymer material.

4. The electronic device according to claim 3, wherein the polymer material is selected from the group consisting of PC, PS, PVC, ABS, PMMA, MPPO, PSF, PES, PEI, PAI, PU, PET, and a combination thereof.

5. The electronic device according to claim 1, wherein the cover further has an opening, and the display module is exposed to the opening.

6. The electronic device according to claim 1, further comprising:
a pressing assembly and a touching assembly exposed to the casing.

7. The electronic device according to claim 1, further comprising:
at least one hinge, the cover pivotally connected with the casing via the hinge.

8. The electronic device according to claim 7, wherein the electrical connection element passes through the light-transparent portion of the cover and enters into the casing along the hinge to allow the display module to be electrically connected with the circuit board.

9. The electronic device according to claim 1, wherein the electrical connection element is a wire or a flexible printed circuit.

10. The electronic device according to claim 1, wherein the electronic device is a notebook computer, a tablet computer, a mobile communication device, a personal digital assistant, a global positioning system, or a display.
